(19) United States
(12) Patent Application Publication
(10) Pub. No.: US 2026/0293021 A1
(43) Pub. Date: Sep. 24, 2026

(54) Power Electronics Module and Electric Motor

(71) Applicant: Innomotics GmbH, Nürnberg (DE)

(72) Inventor: Frank Brütting, Erlangen (DE)

(73) Assignee: Innomotics GmbH, Nürnberg (DE)

(21) Appl. No.: 18/996,071

(22) PCT Filed: Jul. 5, 2023
(86) PCT No.: PCT/EP2023/068524

§ 371 Date: Jan. 17, 2025

(30) Foreign Application Priority Data
Jul. 20, 2022 (EP) 22185971.3

(51) Int. Cl. H05K 7/14; H02K 1/12; H02K 11/33; H02M 7/00; H05K 7/02; H05K 7/20

(52) U.S. Cl. CPC H05K 7/1407; H02K 1/12; H02K 11/33; H02M 7/003; H05K 7/023; H05K 7/209

(57) ABSTRACT

Various embodiments of the teachings herein include a power electronics module. An example includes: circuit boards; and power electronics components on the circuit boards. Two circuit boards are arranged on two cooling plates arranged parallel to one another. Each cooling plate comprises two cooling surfaces parallel to one another. At least one circuit board is arranged on mutually facing cooling surfaces. The two cooling plates each have two through holes. Two rods penetrate both of the two cooling plates in the through holes. Locking devices on the two rods fix the two cooling plates along a rod axis. Support struts are arranged between two mutually opposed circuit boards. The locking device applies a pre-tension along the rod axes counteracted by the support struts, thereby pressing the circuit boards against the opposing cooling surfaces of the two cooling plates.

### CROSS-REFERENCE TO RELATED APPLICATIONS

This application is a U.S. National Stage Application of International Application No. PCT/EP2023/068524 filed Jul. 5 2023, which designates the United States of America, and claims priority to EP Application No. 22185971.3 filed Jun. 20, 2022, the contents of which are hereby incorporated by reference in their entirety.

### TECHNICAL FIELD

The present disclosure relates to electric motors. Various embodiments include power electronics modules and electric motors having a bar winding on the stator side.

### BACKGROUND

Electric motors can have a bar winding on the stator side. Therein, the stator has a series of bars in place of wound wire conductors as field conductors. As compared with conventional windings, the bars have a low inductance. Therefore, a relatively large current flow is required for the generation of a predetermined magnetic field. A motor with this type of construction is disclosed in EP 3 719 975 A1.

However, due to the low inductance of the bars, this large current flow requires only a relatively low voltage of, for example, 12 V. The low voltage enables the components of the inverter with which the bars are energized to be arranged at small spacings from one another. Thus, the modules of the power electronics can be arranged, for example, on one or more (printed) circuit boards arranged close to the electric motor. The bar windings of the motor can therein be used directly or via electrically conducting bar-like connecting elements as mechanical carriers for the circuit boards.

Since the power electronics need to be cooled, some examples include two water-cooled cooling plates fitted with power electronics on both sides and said electronics are cooled thereby. The higher the currents, the more these cooling and power electronics plates must be cascaded one after the other. If a machine has, for example, 96 phase bars, an inverter plate therefore has 96 individual inverters (wherein, however, the electronics for a plurality of phases can be situated on one circuit board). If a parallel connection of four individual inverters is needed, a complete inverter consists of 384 individual power electronics modules. The cooling plates and the power electronics modules mounted thereon are mechanically connected to one another and together form a power electronics module.

From the standpoint of construction technology, the power electronics modules (circuit boards) are individually screwed onto the cooling body in order to be able to ensure a good contact pressure, and thereby a good heat transfer, between the electronics and the cooling plates. Due to the large number of screws, however, this means a large materials and production expenditure, as well as threaded holes in the cooling plates-which also require many production steps and complicate the placement of the cooling channels within the cooling plates. In addition, space is extremely limited on the power electronics modules, so that here also screw holes including the necessary air and creepage distances need appreciable space so that less circuit board area is available for the power electronics itself. Loose screws can further lead to short circuits in the inverter, so that dispensing with such screws would also offer greater failure-proofing.

The aforementioned production expenditure also applies not only to manufacturing, but also to any servicing of the drive system. The system is specifically designed such that (similarly to HVDC systems) a certain number of individual modules can be dispensed with without any great restriction of the operational capability and these modules can be renewed after a certain time in the context of cyclical servicing. The loosening and securing of this large number of screws therefore enormously slows down the servicing. The construction and servicing problems with the power electronics module are described here, by way of example, for the bar winding motor, although it can also occur in other power electronics applications such as in the HVDC systems mentioned above.

### SUMMARY

Teachings of the present disclosure includes power electronics modules which have a low cost, relative to the prior art, for construction and for servicing. Some examples include an electric motor in which a corresponding power electronics module is structurally integrated. For example, some embodiments include a power electronics module (2) having a plurality of power electronics components (4), which are arranged on a plurality of circuit boards (15), wherein at least two circuit boards (15) are arranged on at least two cooling plates (16) arranged parallel to one another, each with two cooling surfaces (6) arranged parallel to one another, so that at least one circuit board is arranged on mutually facing cooling surfaces of the cooling plates, the cooling plates (16) each have at least two through holes perpendicular to the cooling surfaces (6), wherein at least two rods (20) are provided which penetrate the cooling plates (16) in the through holes (22) and locking devices (24) are provided on the rods (20) for fixing the cooling plates (16) along a rod axis (26), and that support struts (28) are arranged between two mutually opposed circuit boards (16), and by means of the locking device (24), a pre-tension along the rod axes (26) results which the support struts (28) counteract and thereby press the circuit boards (15) against the opposing cooling surfaces (6) of the at least two cooling plates (16).

In some embodiments, the support struts (28) are configured to be able to be resiliently deformed along a force action axis (30) of the support strut (28).

In some embodiments, fixing means (50) are provided on the cooling surfaces (6) for fixing the circuit board (15) in relation to the cooling surface (6).

In some embodiments, the locking device (24) of the rods (20) comprises a screw fixing (32).

In some embodiments, the rods (20) are provided at least partially with a thread.

In some embodiments, the locking device (24) comprises spacing sleeves (34) which are inserted over the rods (20) between two cooling plates (16) in each case.

In some embodiments, the rods (20) have a stepped variable diameter.

In some embodiments, the circuit boards (15) are configured to be circular or annular segmental and the cooling plates (16) are configured to be annular or circular.

As another example, some embodiments include an electric motor (10), having: a stator (11) having a plurality of field conductors (12) configured as bars and a power electronics module (2) as described herein, wherein the field conductors (12) are electrically connected to the power electronics module (2).

In some embodiments, the rods (20) of the power electronics module (2) are configured in the form of current conductors (18) electrically connected to the field conductors (12).

In some embodiments, the rods (20) of the power electronics module (2) are directly connected by means of a fastening device (17) to the field conductors (12).

In some embodiments, the power electronics components (4) are configured for driving the field conductors (12).

In some embodiments, the cooling plate (16) is arranged perpendicularly to the axis (9) of the electric motor (10).

In some embodiments, the power electronics module (2) is configured for driving each of the field conductors (12) with its own phase.

### BRIEF DESCRIPTION OF THE DRAWINGS

Further embodiments of the teachings herein and further features are described in greater detail making reference to the drawings. Features with a designation that are represented in different embodiments are each provided with the same reference sign. The representations are purely schematic representations which entail no restriction to the field of protection. In the drawings:

FIG. 1 shows an example electric motor incorporating teachings of the present disclosure with bar conductor windings and a power electronics module attached thereto;

FIG. 2 shows the same electric motor in a front view;

FIG. 3 shows an enlarged detail view from FIG. 1 of a portion of the power electronics module in a side view;

FIG. 4 shows a schematic representation of an example power electronics module with rods and support struts incorporating teachings of the present disclosure;

FIG. 5 shows a representation similar to FIG. 4 wherein the circuit boards are stacked together in a plurality of levels for individual modules;

FIG. 6 shows a schematic representation of a screw fixing of the locking device at the end side of the power electronics module;

FIG. 7 shows a schematic representation of a rod with a step-wise reduced diameter;

FIG. 8 shows a schematic representation of an alternative embodiment of the support struts incorporating teachings of the present disclosure;

FIG. 9 shows a module with support struts that are part of the locking device incorporating teachings of the present disclosure;

FIG. 10 shows a module with a tensioning belt-like fixing of the locking device incorporating teachings of the present disclosure; and

FIG. 11 shows a module with a screw clamp-like fixing of the locking device incorporating teachings of the present disclosure.

### DETAILED DESCRIPTION

The teachings of the present disclosure include a power electronics module with a plurality of power electronics components arranged on a plurality of circuit boards. Therein, at least two circuit boards are provided on at least two parallel cooling plates, each with two cooling surfaces arranged parallel to one another, wherein at least one circuit board is arranged on mutually facing cooling surfaces of the cooling plates. For an optimized structural space usage, two circuit boards are preferably arranged opposite one another on mutually facing cooling surfaces. The cooling plates themselves each have at least two through holes that are introduced perpendicularly to the cooling surfaces. Furthermore, at least two rods are provided which penetrate the cooling plates in the through holes and provided on the rods are locking devices which serve to fix the cooling plate along a rod axis. This means that the locking fixes the cooling plate with the circuit boards arranged thereon along the rod axis such that the cooling plates are arranged fixed at a particular spacing from one another. Furthermore, support struts are arranged, in each case, between the mutually opposed circuit boards, wherein by means of the locking device, a pre-tension along the rod axis results which the support struts counteract. The pre-tension is thus transferred with opposite sign to the support struts, by which means the circuit boards are pressed against the respective opposingly arranged cooling surfaces of the at least two cooling plates.

Through the combination of the locking device and the support struts which are retained in the assembled state of the power electronics module, a large number of individual screw fixings is rendered superfluous. The support struts press the circuit boards onto the cooling plates without the need for any additional screw fixing. The locking device can therein also be configured such that, in the presence of a plurality of cooling plates, just one fixing, for example, in the form of a screw fixing, is sufficient. During construction or servicing of the power electronics module, this can be inserted, for example, in an assembly device and, by way of the loosening of a few fixings, for example, screws, it can be disassembled such that individual circuit boards can be removed and replaced without any great time expenditure. As compared with the prior art, the assembly and/or servicing effort for the power electronics module is thereby significantly reduced. Furthermore, fewer screws are needed for fixing the circuit boards on the cooling plates, saving material and assembly costs and enabling a greater freedom in the layout of cooling channels in the cooling plates. This, in turn, leads to a more effective cooling of the module and also increases its efficiency.

The cooling plates which, for example, where used for an electric motor that is yet to be described, are preferably configured to be annular or circular, have two approximately parallel cooling surfaces. The cooling surfaces are arranged on opposite sides of the cooling plate, parallel to one another. The cooling surfaces themselves can have surface structuring which serves, for example, for accommodating the circuit boards or which are suitable for purposes of cooling technology. Thus, the cooling surface itself does not necessarily need to be entirely planar. However, it has substantially planar surfaces which are parallel in relation to the opposite cooling surface.

In some embodiments, the support struts are configured to be able to be resiliently deformed along a force action axis. The resilience can be configured, for example, by way of material elasticity, for example, by way of the use of an elastomer as part of the support strut or by way of mechanical spring elements, for example, a coil spring or a leaf spring. In a suitable form, the force action axis of the support struts can extend parallel to the rod axis and can thus extend parallel to the axis of action of the applied pre-tension. The force action axis of the support strut can, however, also extend at a particular angle to this rod axis if the support strut is mounted, for example, in the form of V-shaped or W-shaped braces.

As indicated above in the definition of their parallelism, the cooling surfaces can have fixing means for fixing the circuit board relative to the cooling surfaces. These fixing means can be depressions into which the circuit boards are inserted, although they can also be protruding knobs or slots into which the corresponding recesses in the circuit board lock, similarly to the Lego principle.

In some embodiments, the locking device of the rods has a screw fixing. This screw fixing can be embodied such that for a plurality of cooling plates, just one screw per rod is needed. Therein, the rod preferably has, at least partially, a thread on which a nut can be placed to form the screw fixing. In principle, however, the lockings can alternatively also take place by way of interlockings rather than by way of screw fixings, although it is advantageous that the fixing of the locking device is releasable. An interlocking can take place, for example, by way of a cross key. Furthermore, a locking can take place by way of the pressing on of a further component, for example, an end shield. A clamping device extending round the module can also serve as part of the locking device. Therein, for example, tensioning belt-like devices or screw clamp-like devices are suitable. In the case of a tensioning belt-like device, at least one belt-like or band-like component is laid around the module and is pulled together, for example, with a ratchet, which brings about the fixing. Alternatively, fixings can also similarly be applied from outside, similarly to a screw clamp or a lever clamp as part of the locking device, for fixing.

In some embodiments, the locking device comprises spacing sleeves which are placed over the rods between two cooling plates in each case. These spacing sleeves serve to adjust exactly the spacing between the respective cooling plates, wherein by way of these spacing sleeves, a further screw fixing and/or a further nut on the cooling plates can be dispensed with. This spacing sleeve concept helps to ensure that, where possible, one fixing, that is, a screw fixing, can suffice.

In some embodiments, the rods have a stepped variable diameter similar to that of a stepped drill. The cooling plates can be successively stacked on the rods configured in this manner. It is therein suitable if the through holes also narrow from one cooling plate to the next cooling plate according to the step-shaped change of the diameter of the rod.

In some embodiments, the support struts coincide, in terms of design, with the rods or the locking device if, for example, locking means which have an extent in the region of the through hole along the cooling surfaces are mounted on the sleeves or on the steps of the rods.

In some embodiments, for use in electric motors, the circuit boards are configured to be circular segmental or annular segmental and thus also correspond with annular or circular cooling plates.

Some embodiments include an electric motor with a stator having a plurality of field guides configured as bars and a power electronics module as described herein, wherein the field guides are electrically connected to the power electronics module. An electric motor, in particular, with the bar-conductor motor as described, has very low voltages and very large currents flowing, the power electronics module can be arranged, connected in parallel, directly on the motor and thus integrated therein. In particular, for motors of this design, the advantages described have their effect especially in the construction and servicing of the power electronics.

The electric motor described differs from conventional electric motors at least in that the stator has a series of bars in place of wound wire conductors as field conductors. As compared with conventional windings, the bars have a low inductance. Therefore, a relatively large current flow is required for the generation of a predetermined magnetic field.

From the construction of the bar winding, there follow fundamental advantages in the operation of the machine: due to the segment-wise controllability of the magnetic flux between two field conductors in each case, far more flexible forms of magnetic fields can be applied in the machine than would be possible with a distributed winding and its inherent overlaying effects. By this means, many (control-related) advantages arise with regard to the running properties of the machine. Furthermore, the failure of a phase ((of the energizing) of a field conductor) has far smaller consequences than would be the case, for example, in a double three-phase or even a normal three-phase machine. Since these effects can also be compensated for very well by the adjacent phases, with each phase failure on corresponding correction, almost exclusively the drive output falls by only a small fraction without influencing the remaining properties appreciably.

In some embodiments, the rods of the power electronics module are configured in the form of current conductors electrically connected to the field conductors. This means that the rigid field conductors of the electric motor are also themselves directly and fixedly connected in a conducting manner by means of the rods to the power electronics module. Thus, the rods which firstly serve for the advantageous construction of the power electronics module, simultaneously assume the function of the current conduction of the module to the field conductors of the electric motor. For this purpose also, a fastening device, for example, in the form of a fastening shoe between the field conductors and the rods (current conductors) is also suitable. In this way, the power electronics module can be directly and fixedly arranged on the electric motor and can possibly be integrated into a common housing.

The power electronics components of the module therein serve to drive the field conductors. They are therein connected in parallel along the individual cooling plates and along a motor axis, so that the power electronics module can drive each field conductor with its own phase. In some embodiments, the cooling plates are arranged perpendicularly to the axis of the motor, that is, to the motor axis. Thus, the construction of the electric motor together with the power electronics module can be designed in a particularly space-saving manner.

The construction of a power electronics module, which itself is may be integrated into a bar-conductor motor, will now be described making reference to the drawings. What is disclosed is a particularly suitable application although it can also be transferred to other applications, for example, in the high voltage direct current (HVDC) domain.

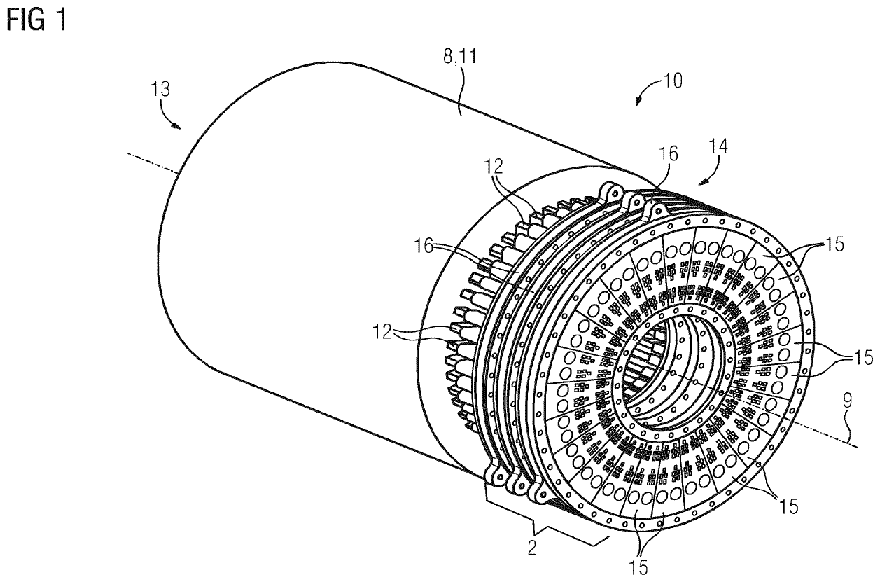

FIG. 1 shows an isometric view of an electric motor 10 incorporating teachings of the present disclosure. The electric motor 10 comprises a stator 11 and a rotor (not shown in FIG. 1) arranged substantially in the stator 11. The rotor is non-rotatably connected to a shaft which is also not shown in FIG. 1. Through electromagnetic interaction of the rotor with a current-conducting stator 11, the rotor is brought into rotation about an axis 9. The rotor is therein separated from the stator 11 by way of an air gap. In some embodiments, the electric motor 10 can also be an external rotor motor or a bell-type armature motor.

The stator 11 comprises, as field conductors, a plurality of rigid and straight conductor bars 12. These conductor bars 12 are connected to one another, on the end side 13 facing away in FIG. 1, via a short-circuiting ring. On the rear side 14 of the electric motor 10, the conductor bars 12 are individually fed by way of respective inverter modules. The inverter modules are parts of a power electronics module 2. Since what is concerned, due to the conductor bars 12, is an electric motor 10 operated at low voltages, the inverter modules can be arranged together with other components of the electronics (DC/DC converters, rectifiers) relatively closely together on circuit boards 15. In this example, the circuit boards 15 are annular segmental and many individual circuit boards 15 together form an annular circuit board structure. The rigidly configured conductor bars can therein be configured from a metallic rod, for example a copper rod or a fixed multifilament conductor.

While, in the examples, it is assumed that the circuit boards 15 carry inverter modules, it is also possible that a portion of the circuit boards 15 carry rectifiers and DC/DC converters.

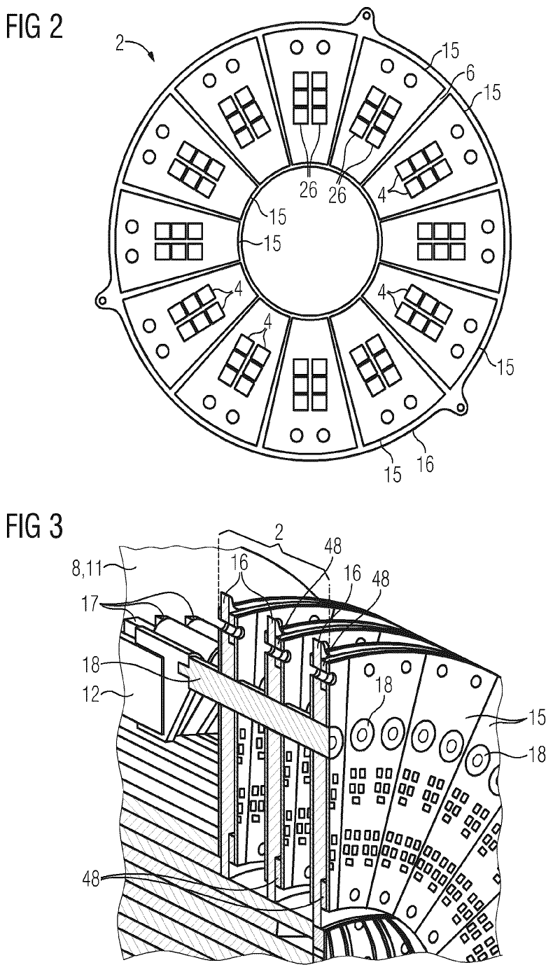

FIG. 2 shows a plan view of such a circuit board structure with individual circuit boards 15. For the sake of better clarity, the number of the circuit boards 15 shown in FIG. 2 is therein shown reduced and greatly simplified as compared with the representation in FIG. 1. The specific number of such circuit boards 15 depends upon the specific embodiment of the electric motor 10, in particular, the number of conductor bars 12. Each of the circuit boards 15 comprises a plurality of power electronics components, in particular, semiconductor switches.

Furthermore, a portion of the circuit boards 15 or all the circuit boards 15 in the drawings comprise driver circuits (not shown) and other electronic components such as capacitors. The semiconductor switches 26 are power semiconductors such as, for example, IGBTS, MOSFETS or JFETs and, dependent upon the interconnection, can additionally comprise diodes (not shown). The semiconductor switches 26 are connected, for example, as half bridges. A capacitor (not shown) can represent, for example, a DC link capacitor of the half bridges. The semiconductor switches 26 of a circuit board 15 can therein be associated with a single phase or, however, a plurality of phases.

The circuit boards 15 further comprise contact sites 40 to which the conductor bars 12 are connected. The circuit boards 15 are carried by disk-shaped cooling plates 16, wherein for an improved space utilization, the cooling plates 16 can be occupied on both sides with circuit boards 15.

Since, in the electric motor 10, as compared with conventional motors having windings, relatively large currents are needed in the conductor bars 12, a plurality of inverters are preferably connected in parallel to supply them with current. This can be achieved, for example, in that the six circuit board structures on three cooling plates 16 shown in FIG. 1 are all similarly connected to the conductor bars 12 and are thus electrically connected in parallel. It is therein made use of that the conductor bars 12 or connecting elements 18 to the conductor bars 12 penetrate the cooling plates 16 and thus also the circuit boards 15 in the same way at the contact sites or, in the case of the outermost cooling plate 16, at least contact them.

FIG. 3 shows a sectional view of the electric motor 10 in an angled view. Herein, it is evident that the connecting elements 18 mechanically support and penetrate the three cooling plates 16. The connecting elements 18 are connected to the conductor bars 12 via fastening devices 17. The inverters, which are arranged on the circuit boards 15 in the regions where one of the connecting elements 18 penetrates a cooling plate 16 are connected in parallel and together provide the current for the conductor bar 12.

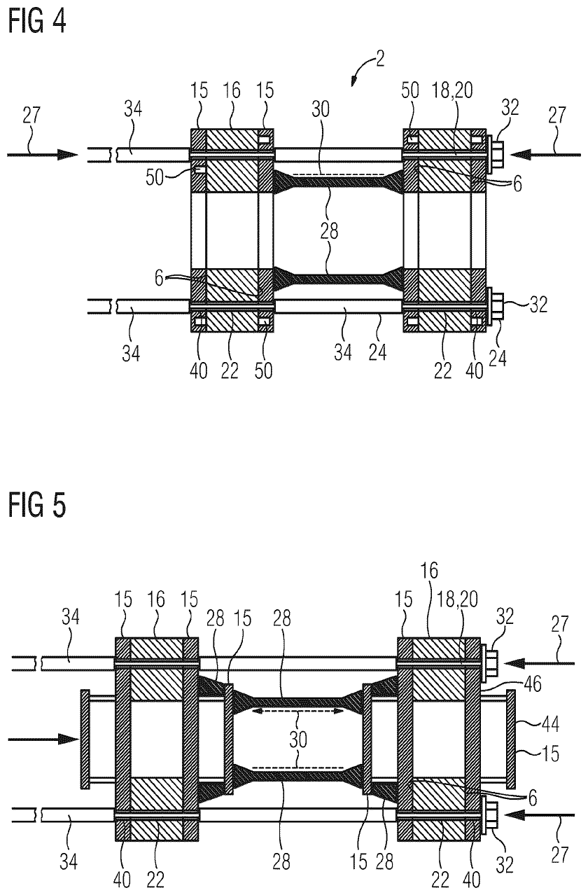

From the examples of the electric motor 10 as described with a bar winding, it is evident, in particular, in FIG. 3 how complex the structure of the power semiconductor module is configured. The cooling plates 16, the circuit boards 15, connecting elements 18 for current supply and possibly current busbars 48 for contacting the circuit boards are individually screwed to one another and assembled. During first construction and servicing of the power electronics module, this implies a very large assembly effort. In FIG. 4, an example is shown of how this assembly effort can be significantly reduced in the power electronics module 2. The power electronics module 2 according to FIG. 4 which is represented here, for better illustration, schematically and simplified, has two cooling plates 16 the cooling surfaces 6 of which are abutted by circuit boards 15. The expression “abutted” herein means that the circuit boards 15 do not necessarily have to be fixed on the cooling surfaces 6.

It is certainly possible for them to be placed precisely at the correct position. In principle, however, it is suitable if fixing means 50 are provided which ensure an exact positioning and a pre-fixing of the circuit boards 15 on the cooling surfaces 6. The fixing means 50 can be depressions, into which the circuit boards 15 are placed, or knobs which themselves penetrate into the recesses in the circuit boards 15. However, a screw fixing of the circuit boards 15 onto the cooling surfaces 6 is not necessary according to this embodiment. This has the result that less effort has to be expended for the assembly and/or also the disassembly of the circuit boards 15. The circuit boards 15 are thus pressed by the support struts 28, during assembly and also in the assembled state, against the cooling surface 6 and thus against the cooling plate 16.

For this purpose, however, a corresponding pressing force is required, which is indicated in FIG. 4 by the force arrows with the reference sign 27. This involves a pre-tension on rods 20 that are fed through the individual cooling plates 16 and through through holes 22 there and, in the example according to FIG. 4, are screwed to an outermost cooling plate 16 by way of a screw fixing 32. Therein, the rods 20 are configured as metallic rods, wherein in the intermediate space between two cooling plates 16, a spacing sleeve 34 is placed over the rod 20 which, due to its defined length, ensures a defined spacing between the plates 16 and/or the circuit boards 15 fixed thereto.

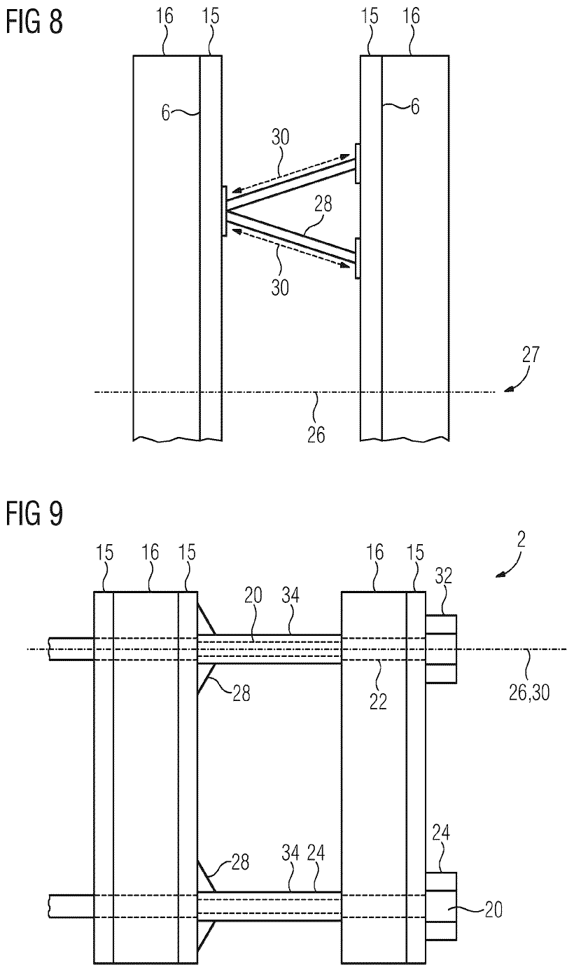

Since the spacing sleeve 34 has a larger diameter than the through holes 22, by tightening the screw fixing 32, the pre-tension 27 against the assembly of the cooling plates 16 described is achieved. The pre-tension 27 is thereby transferred with opposite sign to support struts 28 which, as a direct effect, press the circuit boards 15 against the cooling surfaces 6. A force action axis 30 is therein defined, which in FIG. 4 extends parallel to a rod axis 26. The rod axis 26 itself corresponds to the direction of action of the force 27. The force action axis 30 of the support struts 28 can however also lie at an angle to the rod axis 26, as is shown schematically in FIG. 8.

The construction of the power electronics module 2 illustrated schematically in FIG. 4 therefore shows that an almost arbitrary number of cooling plates with circuit boards 15 abutting them can be stacked beside or on one another. For the construction as shown in FIG. 4, only one screw fixing 32 is necessary. Together with the spacing sleeves 34, this screw fixing 32 forms the locking device 24.

An alternative embodiment of the locking device 24 is shown in FIG. 7. Here there is a screw fixing 32, wherein the rod 20 has a thread 36 at its end side and is thus analogous to FIG. 4. However, the rod 20 according to FIG. 7 has no spacing sleeves 34, rather the constant spacing between two cooling plates 16 is implemented by way of a stepped narrowing along the rod axis 26. For this it is necessary that the through holes 22 of the individual cooling plates 16 along the rod axis 26 also narrow in diameter accordingly so that each step of the rod 20 abuts the circuit board 15 and preferably also at a contacting site there, which is also electrically conductive. The embodiment shown in FIG. 7 is technically somewhat more complex than the locking device 24 according to FIG. 4, although through the application of the pre-tension 27, it is possible with this embodiment to achieve a more effective electrical contact between the rod 20 and the contacting site 40.

The contacting site 40 just described between the rod 20 and the circuit board 15 has significance in that the rod 20 simultaneously represents the connecting element 18 as shown in detail in FIG. 3. The locking device 24 schematically represented in FIGS. 4 to 8 is not shown in this form in FIG. 3. It is also evident in this regard in FIG. 3 how the electrically conducting connecting element 18 is electrically conductively connected via a fastening device 17 to the conductor bars 12 of the electric motor 10. The connecting elements 18 and thus the rods 20 therefore serve for current supply to the conductor bar 12. The power electronics module 2 as described in relation to FIGS. 4 to 8 absorbs said current and uses the connecting elements 18 which are necessary for current feed and for control of the bars 20, as rods 20 for advantageous mounting of the module 2 as described in FIGS. 4 and 5. The power electronics module 2 can thus be placed directly on the electric motor 10 and/or its conductor bars 12 and is thus an integral component of the electric motor 10. It can possibly also be accommodated in a housing which is not shown here, together with the electric motor 10.

It follows therefrom that it is suitable to provide a connecting element 18 and/or a rod 20 with a fixing device 24 for each conductor bar. Due to this arrangement, the power electronics module 2, which is configured rotationally symmetrical, is seated on the axis 9 of the electric motor 10. The connecting elements 12 also extend along and/or parallel to this axis. The circuit boards 16 which are each connected in parallel with a connecting element 12 therein serve for controlling a stack 12. By way of this parallel connection, large currents can be passed on at low voltage directly to the conductor stack 12. Furthermore, each stack 12 can also be driven individually as a separate phase.

Therein, the circuit boards comprise different power electronics modules. Therein, so-called gate drivers 44 and output stages 46 together form a power unit. A plurality of power units with control systems themselves form an inverter. These components and/or component modules can be integrated in a circuit board 15, although they can also be constructed in a plurality of steps and/or in a plurality of levels. A layered construction of this type of circuit boards 15 is shown in FIG. 5. Herein, for example, the gate driver 44 is arranged as the output stage 46 in another circuit board 15. These two circuit boards 15 are arranged over one another, which in the construction of the power electronics module 2 according to FIG. 5 is achieved similarly to FIG. 4, except that possibly further smaller support struts 28 are needed which support the circuit boards 15 stacked upon one another.

Therein, it is suitable for the support struts 28 in FIG. 5 as well as in FIG. 4 that they are capable of being resiliently deformed along their force action axis 30. This is useful in order to cancel out possible tolerances in the overall construction and to prevent damage to the circuit boards 15. Therein, the resilient elements can be material-dependent, for example, elastomers can be used as spring elements, although separate spring elements such as helical springs or leaf springs can also be used.

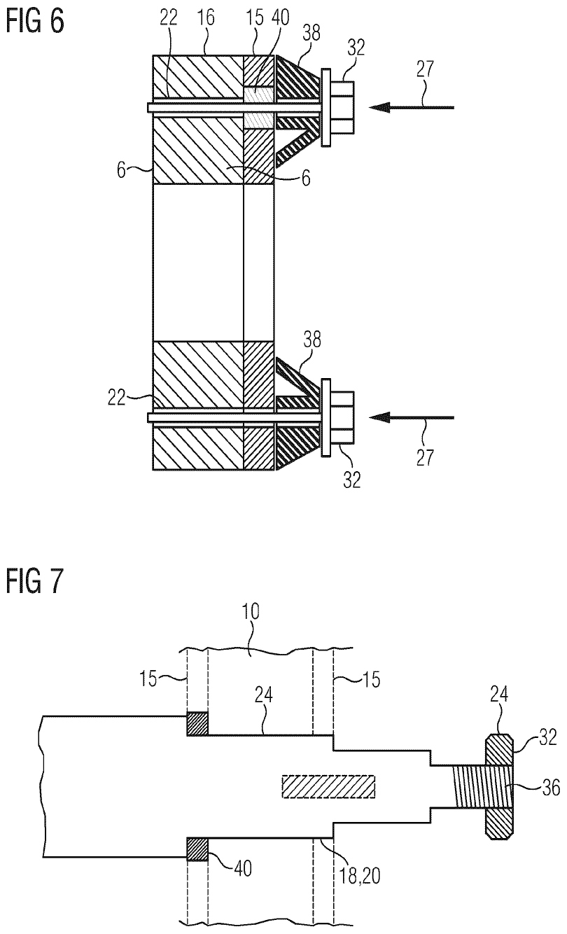

FIG. 6 shows an example of a fastening on the end side of the screw fixing incorporating teachings of the present disclosure. Herein also, it is suitable that for the avoidance of bending stresses on the circuit boards 15, resilient elements, in the form here of end struts 38 are used in order to press the circuit boards 15 against the cooling surfaces 6. This could also take place, in principle, by way of the screw fixing 32. In order to ensure the stability of the circuit boards 15 and for a more spread-out/even force distribution, the arrangement of the end struts is suitable.

The fixing of the fixing device 24 at the end side which is realized, for example, in FIG. 6 with the screw fixing 32 can however also take place with a tensioning of the rod 20 on the end shield of the electric motor 10 (not shown in the drawing). The end shield is typically screwed onto the housing of the electric motor 10 so that here also the screw fixing can be referred to indirectly as a constituent part of the fixing device 24.

It should further be noted that busbars 48 as represented in FIG. 3, but not shown in FIGS. 4 to 8 for the sake of clarity, can be arranged between the cooling plate 16 and the circuit boards 15 in depressions (not shown here) in the cooling plate 16. These busbars 48 are also contacted by way of the described pre-tension 27 of the locking device 24 by way of a particular contact pressure with a contacting site (also not shown here) in the circuit board 15. For these busbars 48, it is also possible that no separate screw fixing, as required according to embodiments from the prior art, is needed.

The concept described for the construction and/or servicing of power electronics modules 2 therefore has a significantly smaller number of required screw fixings as compared with the prior art, which has the result that the construction can be disassembled with the removal of fewer screws and reassembled again. The assembly effort is therefore significantly less than is taught by designs from the prior art. Furthermore, if needed, a defective circuit board and/or a defective power electronics module from the module 2 can be replaced.

Shown schematically in cross-section in FIG. 9 is a power electronics module 2 in which the support struts 28 are configured as a part of the sleeves 34. The support struts are thus integrated into the locking device and, in the cooling surface plane, have an areal broadening for supporting the circuit boards 15. In this drawing, by way of example, with cooling surfaces 6 opposite one another, the circuit board is arranged so that it is not situated directly opposite another circuit board 15. However, in order to optimize the available installation space, typically circuit boards 15 are arranged opposite one another.

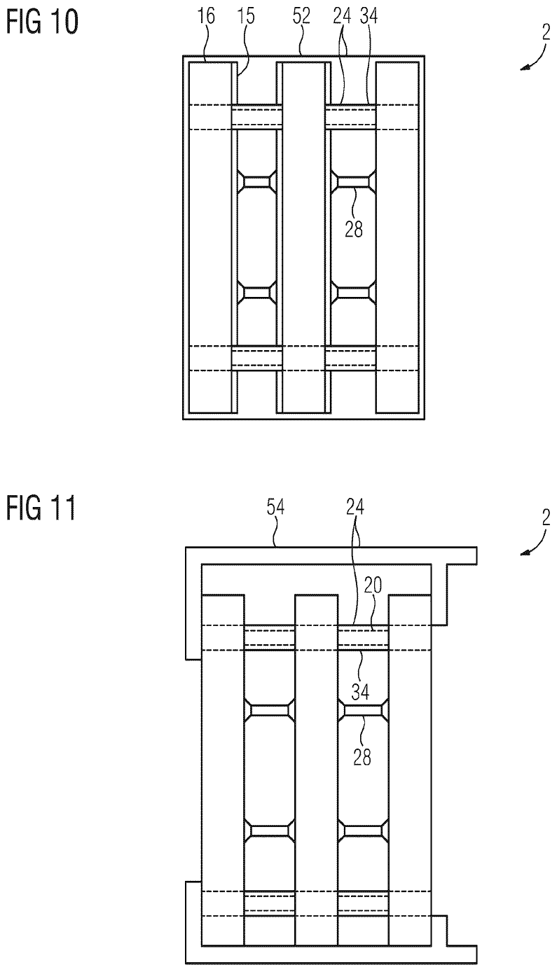

Shown in FIG. 10 is an example of how a tensioning belt-like locking of the cooling plates 16 of the module 2 can together be part of the locking device 24. Herein, as a further part of the locking device 24, the sleeves 34 as described are used. Furthermore, a tensioning belt-like strap 52 is placed round the module 2 and, by means of a ratchet (not shown), it is lashed together, that is, locked.

In some embodiments, the locking can also be carried out with a screw clamp-like fixing, as shown schematically in FIG. 11. For this purpose, a screw clamp 54 or a lever clamp is applied along the rod axis 26 and the module 2 is fixed. Combinations of the representations from FIGS. 4 to 11 are also suitable.

### Reference Signs

2 Power electronics module
4 Power electronics components
6 Cooling surfaces
8 Stator/rotor block
9 Motor axis
10 Electric motor
11 Stator
12 Conductor bars
13 End side
14 Rear side
15 Circuit boards
16 Cooling plate
17 Fastening device
18 Connecting element
20 Rods
22 Through holes
24 Locking device
26 Rod axis
27 Pre-tension
28 Support struts
30 Force action axis
32 Screw fixing
34 Sleeves
36 Thread
38 End struts
40 Contacting site
42 Connecting thread
44 Gate driver
46 Output stage
48 Busbars
50 Fixing for circuit board
52 Tensioning belt-like locking
54 Screw clamp-like locking

What is claimed is:

1. A power electronics module comprising:
a plurality of circuit boards;
a plurality of power electronics components arranged on the plurality of circuit boards;
wherein two circuit boards of the plurality of circuit boards are arranged on two cooling plates, the two cooling plates arranged parallel to one another;
each cooling plate comprises two cooling surfaces parallel to one another;
at least one circuit board is arranged on mutually facing cooling surfaces of the two cooling plates;
the two cooling plates each have two through holes extending perpendicular to the cooling surfaces;
two rods penetrate both of the two cooling plates in the through holes;
locking devices the two rods fix the two cooling plates along a rod axis; and
support struts arranged between two mutually opposed circuit boards;
wherein the locking device applies a pre-tension along the rod axes counteracted by the support struts, thereby pressing the circuit boards against the opposing cooling surfaces of the two cooling plates.

2. The power electronics module as claimed in claim 1, wherein the support struts ARE elastic along a force action axis of the respective support strut.

3. The power electronics module as claimed in claim 1, further comprising fixing means on the cooling surfaces for fixing the circuit board in relation to the respective cooling surface.

4. The power electronics module as claimed in claim 1, wherein the locking device comprises a screw fixing.

5. The power electronics module as claimed in claim 4, wherein each of the rods comprises a thread.

6. The power electronics module as claimed in claim 1, wherein the locking device comprises spacing sleeves inserted over the rods between the two cooling plates.

7. The power electronics module as claimed in claim 1, wherein each of the rods comprises a stepped variable diameter.

8. The power electronics module as claimed in claim 1, wherein:
the two circuit boards are circular or annular segmental; and
the cooling plates are annular or circular.

9. An electric motor comprising:
a stator having a plurality of bar-shaped field conductors connected to a power electronics module;
the power electronic module comprising:
a plurality of circuit boards;
a plurality of power electronics components arranged on the plurality of circuit boards;
wherein two circuit boards of the plurality of circuit boards are arranged on two cooling plates, the two cooling plates arranged parallel to one another;
each cooling plate comprises two cooling surfaces parallel to one another;
at least one circuit board is arranged on mutually facing cooling surfaces of the two cooling plates;
the two cooling plates each have two through holes extending perpendicular to the cooling surfaces;
two rods penetrate both of the two cooling plates in the through holes;
looking devices the two rode fix the two cooling plates along a rod axis; and
support struts arranged between two mutually opposed circuit boards;
wherein the locking device applies a pre-tension along the rod axes counteracted by the support struts, thereby pressing the circuit boards against the opposing cooling surfaces of the two cooling plates.

10. The electric motor as claimed in claim 9, wherein the rods of the power electronics module comprise current conductors electrically connected to the field conductors.

11. The electric motor as claimed in claim 10, wherein the rods of the power electronics module are directly connected by a fastening device to the field conductors.

12. The electric motor as claimed in claim 9, wherein the power electronics components are configured for driving the field conductors.

13. The electric motor as claimed in claim 9, wherein the cooling plate is arranged perpendicularly to the axis of the electric motor.

14. The electric motor as claimed in claim 9, wherein the power electronics module is configured for driving each of the field conductors with its own phase.
